(19) United States
(12) Patent Application Publication
(10) Pub. No.: US 2025/0293176 A1
(43) Pub. Date: Sep. 18, 2025

(54) SYSTEMS AND METHODS FOR COMPONENT ISOLATION

(71) Applicant: Qorvo US, Inc., Greensboro, NC (US)

(72) Inventors: Loizos Loizou, Grasbrunn (DE); Vladimir Kolchuzhin, Hohenschaeftlarn (DE)

(21) Appl. No.: 19/032,579

(22) Filed: Jan. 21, 2025

Related U.S. Application Data
(60) Provisional application No. 63/564,252, filed on Mar. 12, 2024.

(51) Int. Cl. H01L 23/552; H01L 21/56; H01L 23/31; H01L 25/07

(52) U.S. Cl. CPC H01L 23/552; H01L 21/56; H01L 23/3107; H01L 25/072

(57) ABSTRACT

Systems and methods for component isolation are disclosed. In one aspect, one or more ferromagnetic walls may be positioned between components such as for example, filters (acoustic or otherwise), surface-mounted devices (SMDs), amplifiers, switches, or the like. The ferromagnetic walls may be introduced as part of an overmold package and may be thinner than conventional Faraday cages or shields, allowing components to be placed in closer proximity without increasing crosstalk or electromagnetic interference (EMI).

### PRIORITY APPLICATION

The present application claims priority to U.S. Provisional Patent Application Ser. No. 63/564,252, filed on Mar. 12, 2024, and entitled “SYSTEMS AND METHODS FOR COMPONENT ISOLATION,” the contents of which are incorporated herein by reference in its entirety.

### BACKGROUND

### I. Field of the Disclosure

The technology of the disclosure relates generally to component packages and is particularly well suited for radio frequency (RF) component packages and modules.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. Concurrent with this increased functionality is a perceived pressure to continue to decrease component size within the mobile communication device. This trend is not unique to mobile communication devices and is present in other devices as well. The general trend is to have more dense and compact printed circuit boards, which results in components being placed near one another. Where transmitter and receiver components are in close proximity, there may be unwanted crosstalk or other electromagnetic interference (EMI), particularly at radio frequencies. Providing isolation in such cramped quarters provides room for innovation.

### SUMMARY

Aspects disclosed in the detailed description include systems and methods for component isolation. In particular, aspects of the present disclosure contemplate using one or more absorbing walls that may be ferromagnetic isolation walls between components such as, for example, filters (acoustic or otherwise), surface-mounted devices (SMDs), amplifiers (e.g., power amplifiers and low noise amplifiers), switches, or the like. The absorbing isolation walls may be introduced as part of an overmold package (or undermold (e.g., double sided ball grid array (DSBGA) or double sided molded ball grid array (DSMBGA)) and may be thinner than conventional Faraday cages or shields, allowing components to be placed in closer proximity without increasing crosstalk or electromagnetic interference (EMI). While particularly useful for radio frequencies, it should be appreciated that the teachings may have broader application.

In this regard, in one aspect, a package is disclosed. The package comprising: a laminate, a first component, a second component proximate to the first component and at least one absorbing isolation wall positioned between the first component and the second component, the at least one absorbing isolation wall configured to reduce electromagnetic emissions between the first and second components.

In another aspect, a communication device is disclosed. The communication device includes a transceiver chain comprising a package, the package comprising: a laminate, a first component, a second component proximate to the first component, and at least one ferromagnetic isolation wall positioned between the first component and the second component, the at least one ferromagnetic isolation wall configured to reduce electromagnetic emissions between the first and second components.

In another aspect, a method of forming a package is disclosed. The method includes placing a first component on a laminate, placing mold material over the first component, forming a trench in the mold material, and filling the trench with a ferromagnetic material.

In another aspect, a method of forming a package is disclosed. The method includes placing a first component on a laminate, placing mold compound around the first component, forming a trench in the mold compound, and filling the trench with a ferromagnetic material.

### BRIEF DESCRIPTION OF THE DRAWINGS

FIG. 1A is a front perspective view of a pair of components mounted on a printed circuit board (PCB) without any isolation;

FIG. 1B is a front elevational view of the pair of components of FIG. 1A;

FIG. 1C is a top-plan view of the pair of components of FIG. 1A;

FIG. 2A is a front perspective view of a pair of components with an absorbing isolation wall placed therebetween according to exemplary aspects of the present disclosure;

FIG. 2B is a front elevational view of the pair of components of FIG. 2A;

FIG. 2C is a top-plan view of the pair of components of FIG. 2A;

FIG. 3A is a front elevational view of a pair of components with respective absorbing isolation boxes placed therearound according to exemplary aspects of the present disclosure;

FIG. 3B is a front elevational view of the pair of components of FIG. 3A;

FIG. 3C is a top-plan view of the pair of components of FIG. 3A;

FIGS. 4-9 are top-plan views of a variety of absorbing isolation wall configurations that may be used by exemplary aspects of the present disclosure;

FIG. 10 is a flowchart illustrating a process for forming isolated components;

FIGS. 11A-11F represent side elevation views of a work product as it undergoes the forming of the process of FIG. 10; and

FIG. 12 is a block diagram of a mobile terminal, which, according to the present disclosure, may include the isolation techniques of FIGS. 2A-9.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figure, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like, but generally does not include the power amplifiers. As used herein, the term transceiver is used in the first sense. Where relevant to distinguish between the two definitions, the terms “transceiver chain” and “transceiver circuit” are used respectively. Aspects of the present disclosure are well suited for use in the front end module that contains the power amplifiers as the issues being resolved are more pronounced under large signal conditions such as exist after the power amplifier.

Aspects disclosed in the detailed description include systems and methods for component isolation. In particular, aspects of the present disclosure contemplate using one or more absorbing walls that may be ferromagnetic isolation walls between components such as for example, filters (acoustic or otherwise), surface-mounted devices (SMDs), amplifiers (e.g., power amplifiers and low noise amplifiers), switches, or the like. The absorbing isolation walls may be introduced as part of an overmold package (or undermold (e.g., double sided ball grid array (DSBGA) or double sided molded ball grid array (DSMBGA)) and may be thinner than conventional Faraday cages or shields, allowing components to be placed in closer proximity without increasing crosstalk or electromagnetic interference (EMI). While particularly useful for radio frequencies, it should be appreciated that the teachings may have broader application.

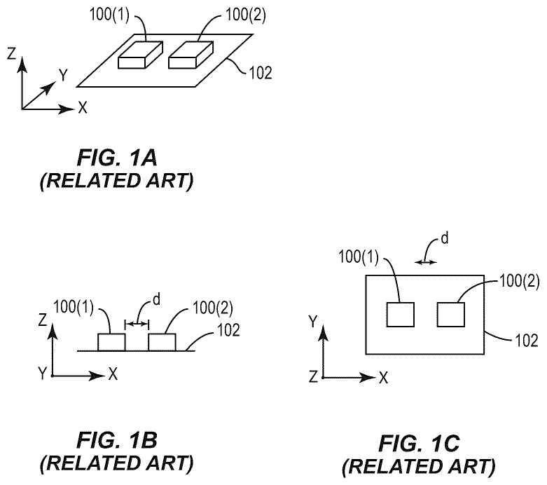

In this regard, FIGS. 1A-1C illustrate two components 100(1)-100(2) mounted on a substrate or laminate such as a printed circuit board (PCB) 102 separated by a distance d. While not shown explicitly, it should be appreciated that in most conventional packages, there is some form of mold compound encapsulating the components 100(1)-100(2). The components 100(1)-100(2) can be filters, acoustic or otherwise, SMDs, amplifiers (power amplifiers, low noise amplifiers, or the like), switches, chips containing integrated circuits, multiplexers, other elements, or combinations of these. The components 100(1)-100(2) may be part of a functional unit (e.g., a transceiver or transceiver chain) in a larger device such as a mobile terminal. The components 100(1)-100(2) may have electromagnetic emissions, which may induce currents or electrical fields in nearby components (i.e., crosstalk or EMI). In many cases, these induced currents are undesirable and may negatively impact the performance of the functional unit or larger device. In general, the closer the component 100(1) or 100(2) is to another component (either the other one of the components 100(1) or 100(2) or some other component not illustrated), the stronger the induced current. The easy solution is to spread the components 100(1)-100(2) apart by a large distance d. However, current commercial pressures, particularly for mobile communication devices, are to compress components 100(1)-100(2) on the PCB 102 to a small distance d and accept the crosstalk/EMI. That is, there is pressure for continuous miniaturization or shrinkage of absolute size of components with commensurate shrinkage of space between the components.

When design constraints force a small distance d, and the crosstalk/EMI exceeds acceptable limits, the typical approach is to use a shield made of conductive material placed between or around (e.g., a cage including a top shield) the individual components 100(1)-100(2). The most effective shields are those connected to a ground plane in the laminate as well as a top conductive shield. In some cases, the shield may be formed from bonded wire mesh. However, current assembly techniques are reaching a limit on how close components 100(1)-100(2) may be (i.e., how small distance d can be) because there is a minimum space between a component 100(1) and a shield, a minimum thickness of the shield, and another minimum space between the shield and the component 100(2). For example, using typical assembly processes, elements are generally at least eighty microns from one another. A bond-wire is typically sixty-five microns, so distance d is 225 microns (component to bond-wire (80)+thickness of bond-wire (65)+bond-wire to component (80) (80+65+80=225)). A full Faraday cage is heavy and makes assembly challenging as well as expensive.

Aspects of the present disclosure use a ferromagnetic material to form a thin isolation wall between components during packaging (as opposed to during assembly). While “thin” is a relative term, for the purposes of the present disclosure, thin means between five and fifty-five microns thick, and in an exemplary aspect, thin is less than approximately twenty-five microns, and in a specific aspect, less than or equal to approximately twenty microns, where approximately is a tolerance of five percent. The ferromagnetic material acts as an absorbing material rather than a shield and absorbs or at least reduces electromagnetic emissions from the components. More specifically, one or more absorbing isolation walls up to a box may be positioned between and/or around the components. The ferromagnetic material may be introduced during packaging, such as during the creation of an overmold, an undermold, or other mold material, and thus is not limited by the same space constraints of a conventional shield formed during assembly.

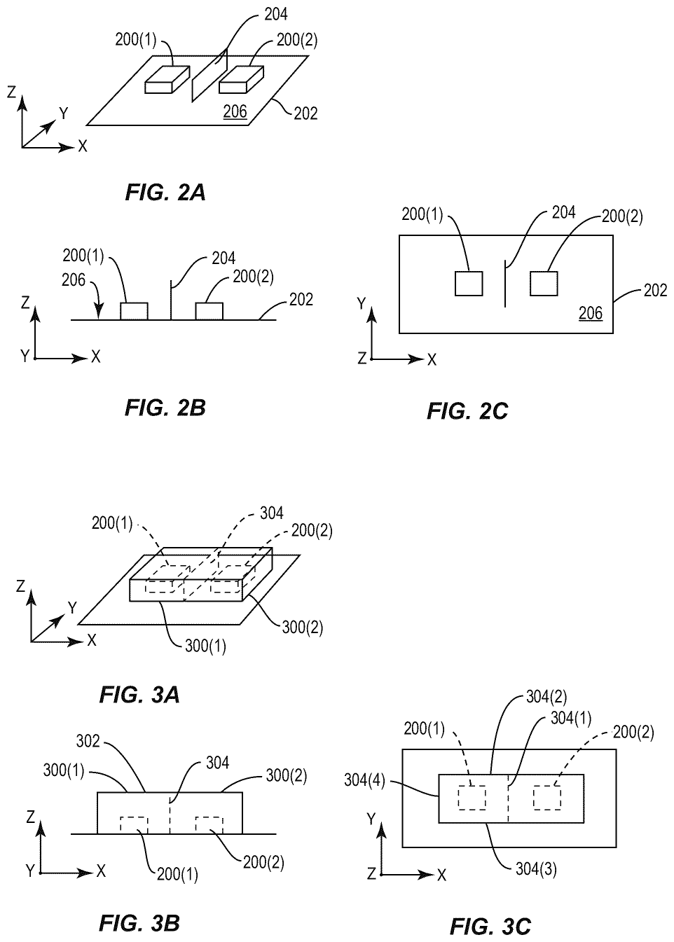

In this regard, FIGS. 2A-2C illustrate a pair of components 200(1)-200(2) on a substrate or laminate PCB 202 with a ferromagnetic isolation wall 204 positioned between them. In an exemplary aspect, an appropriate material for the isolation wall 204 is H5A, sold by the TDK Product Center (www.product.tdk.com). H5A is a manganese—zinc (Mn—Zn) ferrite material. This material is substantially cheaper than the gold or silver that is frequently used for electromagnetic shields. While H5A is specifically contemplated, other ferrite materials may be used in place thereof.

In an exemplary aspect, the isolation wall 204 extends from a top surface 206 of the PCB 202. In an alternate aspect, not shown, the isolation wall 204 extends down into the PCB 202 and may connect with a groundplane (also not shown) or other conductive metal layer in the PCB 202. Note that because the isolation wall 204 has a low conductivity, connection to such a groundplane does not turn the isolation wall 204 into an electromagnetic shield or make the isolation wall 204 an electrical extension of the groundplane.

In a further exemplary aspect, the isolation wall 204 may extend upwardly (away from the top surface 206 along the z-axis) to a top shield (not illustrated), which may be a conductive material rather than a ferromagnetic material. Note that this coupling to either the top surface 206 and/or the top shield is optional. Even when there is a physical connection between the isolation wall 204 and the top surface 206 or top shield, there is no practical electrical connection as the isolation wall 204 is generally non-conductive by virtue of its ferromagnetic nature.

In another exemplary aspect, instead of a single wall 204, the ferromagnetic material may be formed into a box as better illustrated in FIGS. 3A-3C, where the components 200(1)-200(2) are positioned within boxes 300(1)-300(2) respectively. The boxes 300(1)-300(2) may include five (5) sides (albeit with a shared wall), including a horizontal top 302 that extends in the x-y plane and four vertical walls 304(1)-304(4) that extend upwardly from the top surface 206 of the PCB 202 along the z-axis (with wall 304(1) being the shared wall). As with the isolation wall 204, the vertical walls 304(1)-304(4) may extend downwardly into the PCB 202 and may optionally be coupled to a groundplane or other metal layer within the PCB 202.

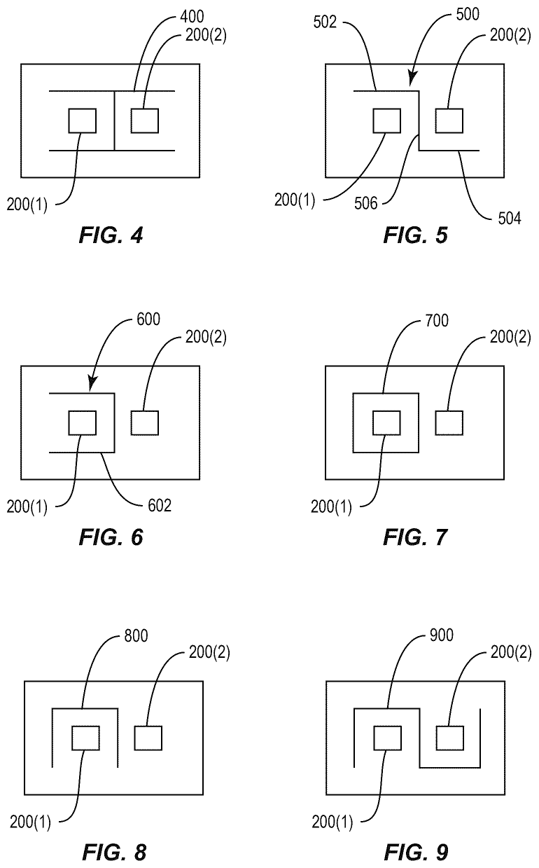

It should be appreciated that one or more isolation walls may be used to form an absorbing barrier between components. Likewise, the configuration of isolation walls may be varied without departing from the present disclosure. In this regard, FIGS. 4-9 illustrate some of the possible isolation wall arrangements, with the understanding that other arrangements, not specifically illustrated may also be used without departing from the present disclosure. FIG. 4, for example, illustrates a generally I- or H-shaped isolation wall 400 with isolation wall segments arranged in separate outwardly facing U-shaped locations where the components 200(1)-200(2) are located. FIG. 5 illustrates a generally reversed S-shaped isolation wall 500 that only has two lateral segments 502, 504 to accompany the shared isolation wall 506. A non-reversed S-shaped isolation wall is also contemplated. FIG. 6 illustrates a generally reversed C-shaped isolation wall 600 that has U-shaped chamber 602 around the component 200(1), but no isolation surrounding the component 200(2). Note that a non-reversed C-shaped isolation wall is also contemplated. FIG. 7 illustrates a topography where only one component 200(1) is contained within a box 700. FIG. 8 illustrates a generally n-shaped isolation wall 800 where only the component 200(1) has walls or segments on multiple sides. FIG. 9 illustrates a lazy-S isolation wall 900.

Note that in all the aspects illustrated in FIGS. 4-9 (as well as other variations discussed but not explicitly illustrated), there remains an isolation wall (or at least a segment of the isolation wall) between the components 200(1)-200(2) but spaced from both. It should be appreciated that other configurations for an isolation wall may be used without departing from the present disclosure, including an isolation wall with non-continuous segments but in each aspect, there would be at least one segment or isolation wall between the components. Likewise, while not explicitly illustrated, any of the aspects illustrated in FIGS. 4-9 may include a top shield because the top shield does not contribute to the required spacing between components.

Note further that while all the examples provided contemplate a shared isolation wall (e.g., wall 204 or 304(4)) between the two components 200(1)-200(2), the present disclosure is not so limited and instead two isolation walls parallel to one another may be provided between the components. Note that this approach is more space-intensive but would provide greater isolation.

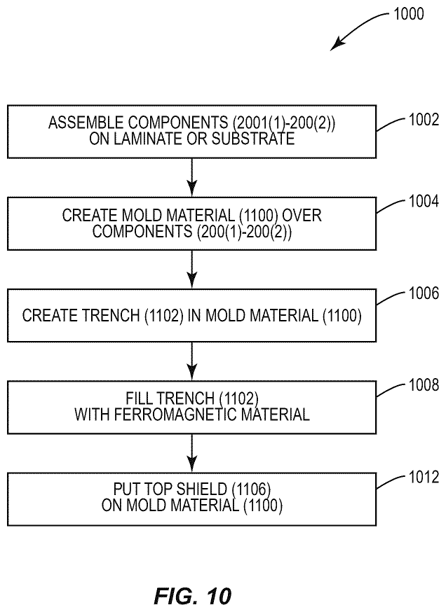

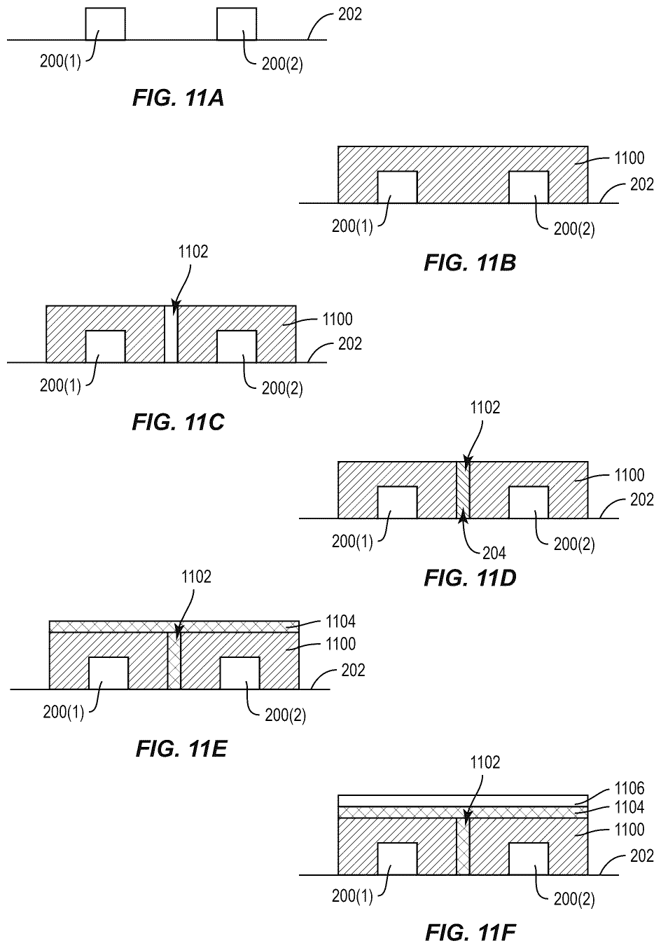

Against this backdrop, FIG. 10 illustrates a flowchart of a process 1000 for forming a package according to aspects of the present disclosure. FIGS. 11A-11F provide supporting illustrations of the various stages of the formation set forth in the process 1000. The process 1000 begins by assembling components 200(1)-200(2) on a laminate or substrate (block 1002, see FIG. 11A). Note that the laminate or substrate may be PCB 202. Further note that while the discussion has generally been presented in terms of just two components 200(1)-200(2), the present disclosure is readily extended to more than two components.

The process 1000 continues by creating an overmold 1100 over the components 200(1)-200(2) (block 1004, see FIG. 11B). A trench 1102 is then formed in the overmold 1100 (block 1006, see FIG. 11C). The trench 1102 may be formed by milling or etching with a mask used to outline the portion to be etched, laser etching, or the like. While only a single isolation wall segment is shown, it should be appreciated that the trench 1102 so created may allow the creation of multiple wall segments. The trench 1102 is then filled with ferromagnetic material (block 1008, see FIG. 11D). A top shield 1106 is then formed over the overmold 1100 (block 1012, see FIG. 11F).

Note while the above discussion specifically contemplates an overmold, it should be appreciated that the steps are readily modified for an undermold (e.g., a die side structure). Accordingly, as used herein a “mold material” contemplates both over and undermold structures. That is, the present disclosure specifically contemplates using an isolation wall between components regardless of on which “side” of the laminate the components are positioned (e.g., top side, back side, both sides, or what have you). Thus, components on a back side of a laminate as may occur in DSBGA or DSLGA packages may benefit from aspects of the present disclosure.

Note further, there may be situations where the isolation wall is preconstructed and such structure is deposited or assembled in place before application of the mold material.

Note that while all of the structures illustrated herein are generally rectilinear, the present disclosure is not so limited, and a honeycomb-like structure or other polygons and spline-like could be used (e.g., pentagons, hexagons, octagons, or the like).

The systems and methods for component isolation, according to aspects disclosed herein, may be provided in or integrated into any processor-based device. Examples, without limitation, include a base station, small cell station, set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

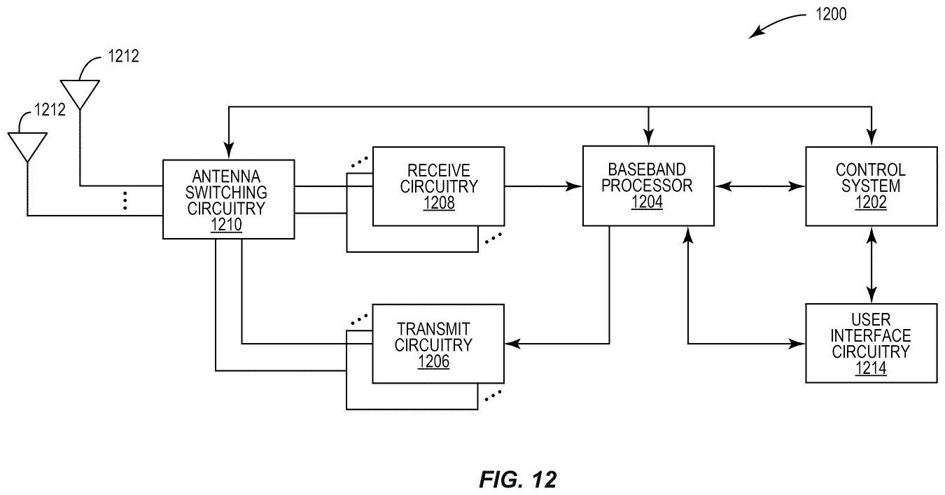

With reference to FIG. 12, the concepts described above may be implemented in various types of user elements 1200, such as mobile terminals, smart watches, tablets, computers, navigation devices, access points, and like wireless communication devices that support wireless communications, such as cellular, wireless local area network (WLAN), Bluetooth, and near field communications. The user elements 1200 will generally include a control system 1202, a baseband processor 1204, transmit circuitry 1206, receive circuitry 1208, antenna switching circuitry 1210, multiple antennas 1212, and user interface circuitry 1214. In a non-limiting example, the control system 1202 can be a field-programmable gate array (FPGA) or an application-specific integrated circuit (ASIC), as an example. In this regard, the control system 1202 can include at least a microprocessor(s), an embedded memory circuit(s), and a communication bus interface(s). The receive circuitry 1208 receives radio frequency signals via the antennas 1212 and through the antenna switching circuitry 1210 from one or more base stations. A low noise amplifier and a filter of the receive circuitry 1208 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1204 processes the digitized received signal to extract the information or data bits conveyed in the received signal. This processing typically comprises demodulation, decoding, and error correction operations. The baseband processor 1204 is generally implemented in one or more digital signal processors (DSPs) and ASICs.

For transmission, the baseband processor 1204 receives digitized data, which may represent voice, data, or control information, from the control system 1202, which it encodes for transmission. The encoded data is output to the transmit circuitry 1206, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1212 through the antenna switching circuitry 1210 to the antennas 1212. The multiple antennas 1212 and the replicated transmit and receive circuitries 1206, 1208 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a laminate;
a first component;
a second component proximate to the first component; and
at least one absorbing isolation wall positioned between the first component and the second component, the at least one absorbing isolation wall configured to reduce electromagnetic emissions between the first and second components.

2. The package of claim 1, further comprising a mold material covering the first component and the second component.

3. The package of claim 2, wherein the mold material comprises a trench and the at least one absorbing isolation wall is positioned in the trench.

4. The package of claim 1, wherein the at least one absorbing isolation wall is positioned on a top surface of the laminate and extends along an axis away from a plane formed by the top surface.

5. The package of claim 2, further comprising a conductive top shield positioned over the mold material.

6. The package of claim 1, wherein the at least one absorbing isolation wall comprises at four walls and a top to form a box around the first component.

7. The package of claim 1, wherein the at least one absorbing isolation wall has a thickness between five and fifty microns.

8. The package of claim 7, wherein the thickness is approximately twenty microns.

9. The package of claim 1, wherein the at least one absorbing isolation wall comprises H5A material.

10. The package of claim 1, wherein the at least one absorbing isolation wall comprises manganese-zinc material.

11. The package of claim 1, wherein the laminate comprises a printed circuit board.

12. The package of claim 1, wherein the first component is selected from the group consisting of: an amplifier, a surface-mounted device, a multiplexer, a filter, and a chip.

13. The package of claim 1, wherein the components are positioned on a backside of the laminate.

14. A communication device comprising:
a transceiver chain comprising a package, the package comprising:
a laminate;
a first component;
a second component proximate to the first component; and
at least one ferromagnetic isolation wall positioned between the first component and the second component, the at least one ferromagnetic isolation wall configured to absorb electromagnetic emissions between the first and second components.

15. A method of forming a package, comprising:
placing a first component on a laminate;
placing a mold material over the first component;
forming a trench in the mold material; and
filling the trench with a ferromagnetic material.

16. The method of claim 15, further comprising placing a second component on the laminate and forming the trench between the first component and the second component.

17. The method of claim 15, further comprising forming a box of ferromagnetic material around the first component.

18. The method of claim 15, wherein filling the trench with the ferromagnetic material comprises filling the trench with manganese-zinc material.

19. The method of claim 15, wherein placing the first component comprises placing a component from the group consisting of: an amplifier, a surface-mounted device, a multiplexer, a filter, and a chip.

20. The method of claim 15, wherein the trench is between five and fifty microns wide.
